(19) United States
(12) Patent Application Publication
(10) Pub. No.: US 2003/0141782 A1
(43) Pub. Date: Jul. 31, 2003

(54) Building component with constant distorsion-free bonding, and method for bonding

(76) Inventors: Bernhard Bader, Munich (DE); Peter Geschka, Neubiberg (DE); Jurgen Agrikola, Eltmann-Lembach (DE)

Correspondence Address: Alan D Smith, Fish & Richardson, 225 Franklin Street, Boston, MA, 02110-2804, US

(21) Appl. No.: 10/203,582

(22) PCT Filed: Feb. 2, 2001
(86) PCT No.: PCT/DE01/00403

(30) Foreign Application Priority Data
Feb. 14, 2000 (DE) 10006447.7

(51) Int. Cl. H01L 41/08

(52) U.S. Cl. 310/313 R; 156/292

(57) ABSTRACT

For gluing stress-sensitive component substrates (BS) having a system carrier (ST), it is proposed to provide spacing structures (AS) between the two surfaces to be glued, the structures assuring a defined arrangement of the two surfaces to be glued. The spacing structures can be created through a screening process, and the space between the spacing structures can be filled with glue (K).

Miniaturized electrical and electronic components are usually inserted into a housing and glued there using a die-bond gluing method. In components that react to mechanical stresses by altering their properties, the use of this gluing method in automated production results in a greater scattering range of component properties than existed prior to the gluing process. This is due to different expansion coefficients of the component and its support or housing. The stress increases when the glued spot is cured at a temperature above the operating temperature of the component and is therefore only stress-free at this curing temperature.

The piezoelectric substrates of surface acoustic wave (SAW) components make them very sensitive to stress. When the components of an SAW are glued in the foregoing manner, for example in a housing, they exhibit an increased scattering of component properties, particularly the mean frequency of the components. If these scattering properties are subject to narrow specifications, such as for the mean frequency of resonators and intermediate frequency (IF) filters, the scattering of the properties reduces the number of components having properties that lie within specified ranges.

Heretofore, costly measures have been necessary to reduce the scattering of component properties following the gluing process. For example, it is possible to increase the specifications and dimensional stability of the parts to be glued. Another option is to improve the precision of the die-bond glue application. In this case, however, it is necessary to view the process in order to monitor the applied quantity of glue. It is also possible to prevent additional stress by optimizing the further steps involved in producing the housing that may also lead to additional stresses.

A drawback of the foregoing measures is their high cost. Furthermore, the effects of fluctuations in vendor parts and procedural changes on the stress-sensitive components cannot be prevented altogether. Another problem associated with increased component miniaturization is that increasingly smaller dimensions lead to thinner materials, which are correspondingly more susceptible to bending and irregularities.

It is therefore the object of the present invention to provide an adhesive connection for a stress-sensitive component, whose structural constitution naturally leads to a constant stressing and therefore to components having a lower error scattering. In addition, it is an object of the invention to provide an adhesive connection that is simple to produce.

In accordance with the invention, the objects are accomplished by a component as defined in claim 1. Advantageous embodiments of the invention, and a method for limiting error scattering in the adhesive connection, ensue from the other claims.

According to the invention, a sensitive crystalline substrate supporting the component structures is connected to a system carrier by a glue. Spacing structures are disposed in a regular pattern between the substrate and the system carrier. Contact points or surfaces are formed in one plane. The substrate and/or the system carrier rests on these contact points or surfaces. Also provided is a spacing structure that forms contact points lying in a straight line. A direct contact is established between the system carrier and the substrate as an additional support point. The space between the spacing structures, the substrate, and the system carrier may be completely filled with glue and extensively free from air, or is partially filled with glue.

In accordance with the invention, therefore, the arrangement and number of contact points or surfaces and the angle between the substrate and the system carrier are predetermined. In a conventional automated die-bond method, more often than not, this was left to chance, and resulted in undefined contact points, which led to different stresses due to fluctuations in the material stability of the system carrier. The spacing between the substrate and the system carrier, as specified by the contact points or surfaces, assures a sufficiently thick layer of glue between the substrate and the system carrier for all of the produced components. An adequately thick glue layer thickness assures sufficient damping of the stress between the different glued materials of the component and the system carrier. This method produces components that only exhibit a low scattering of their properties, even within high piece number batches, and can therefore be produced with a high reproducibility and thus a lower rejection rate.

In an embodiment of the invention, the provided spacing structures form dot-shaped contact points. It is advantageous to provide three or four dot-shaped contact points that correspond to the size of the component substrate to be glued, and are distributed evenly over the surfaces to be glued. An embodiment with three contact points has the advantage that the contact points always lie in one plane.

In an advantageous embodiment of the invention, strip-shaped spacing structures forming parallel, strip-shaped contact surfaces are provided. These strip-shaped spacing structures are particularly advantageous when they have a break in the center. This creates an opening that permits a better distribution of the quantity of glue during the gluing process. The space between the spacing structures, the substrate and the system carrier is therefore filled with glue. This results in a defined volume and defined limits of the glue layer; coupled with good reproducibility. This allows the properties of the layer to be maintained at a more consistent level.

The spacing structures preferably comprise a screenable mass that is applied to the system carrier or substrate through a screening process. Spacing structures can be particularly simply produced in this manner. It is ensured, however, that uniformly high spacing structures or contact points or surfaces lying in one plane can be formed. The invention is especially advantageous for frequency-accurate, surface acoustic wave elements that remain stable in frequency with the adhesive connection according to the invention, so only a slight error scattering in the mean frequency is observed in mass production.

The invention can be used to compensate for unavoidable uneven spots in the surface of the system carrier, and to ensure a uniform layer thickness of the glue applied between the substrate and the system carrier in the die-bond method. The advantages of the invention can therefore also be attained with increasingly thinner materials, despite their greater susceptibility to bending and uneven spots. The gluing process becomes more stable and less sensitive to fluctuations in the quality of the system carrier and the glue application.

The invention is suitable for all components on crystalline substrates, in particular for components that are sensitive to stresses. Examples include electrical, electronic and particularly passive components, such as the aforementioned surface acoustic wave (SAW) components.

The system carrier can be a circuit board, particularly a multiple-layer plastic board comprising numerous metallization layers, a ceramic substrate board that may contain conductive tracks and/or feed-throughs, or a two-part housing, in which case the substrate may be connected to the housing floor or the housing cover. The housing may comprise ceramic or metal.

As mentioned above, the spacing structures preferably comprise screened structures. It is also possible, however, to produce the spacing structures from other materials, especially metal, glass or mixed organic/inorganic pastes, such as metallization pastes that can be screened. Accordingly, the spacing structures can be created directly on one of the substrate or system-carrier surfaces, or be mounted to them in prefabricated form. For creating the structures directly on the substrate or system-carrier surface, for example, a layer of an appropriate material is first applied to the entire surface in the desired thickness, then worked so as to produce the spacing structures. If desired, the spacing structures may be mounted to the surface of the substrate or system carrier.

The glue used is preferably a thermally curable elastomer. With corresponding application devices, the elastomer can be applied in extremely small quantities and at the desired locations for tiny components.

The dimensions of the spacing structures are a function of the size and type of the component to be glued. Generally, however, a height of 10 μm to 50 μm suffices. This height also determines the thickness of the glue layer, which suffices to absorb the majority of the stress gradients between the different materials. Thus, the majority of the stress can be localized inside the glue layer.

While the spacing structures form defined contact points and surfaces, when the glue is applied, a thin glue layer, typically about 1 μm thick, is also formed between these contact points and surfaces and the surface to be glued. This is small compared to the thickness of the total glue layer, however, and does not diminish the advantages attained with the invention. If desired, the space between the substrate, the system carrier, and the spacing structures may be completely filled with glue, without containing air.

The invention is described in detail below by way of exemplary embodiments and the attached figures.

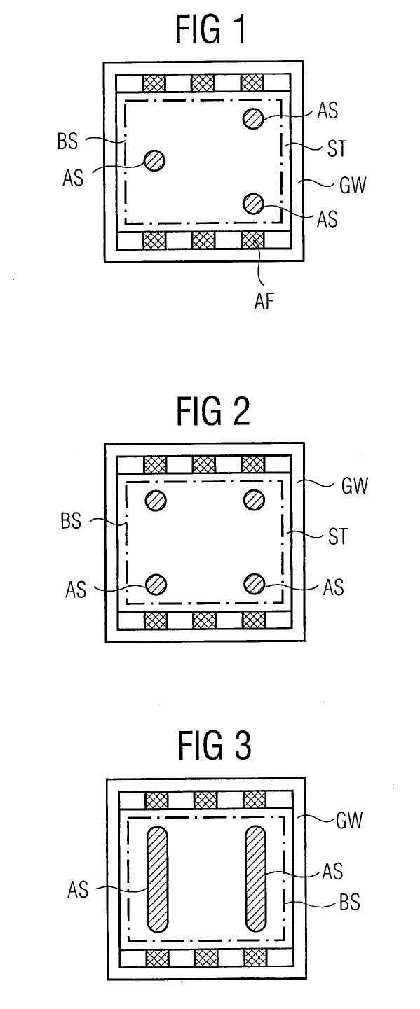

FIGS. 1 through 4 show a schematic, plan view of a system carrier with different spacing structures.

FIG. 5 is a schematic cross-section of a substrate connected to a system carrier.

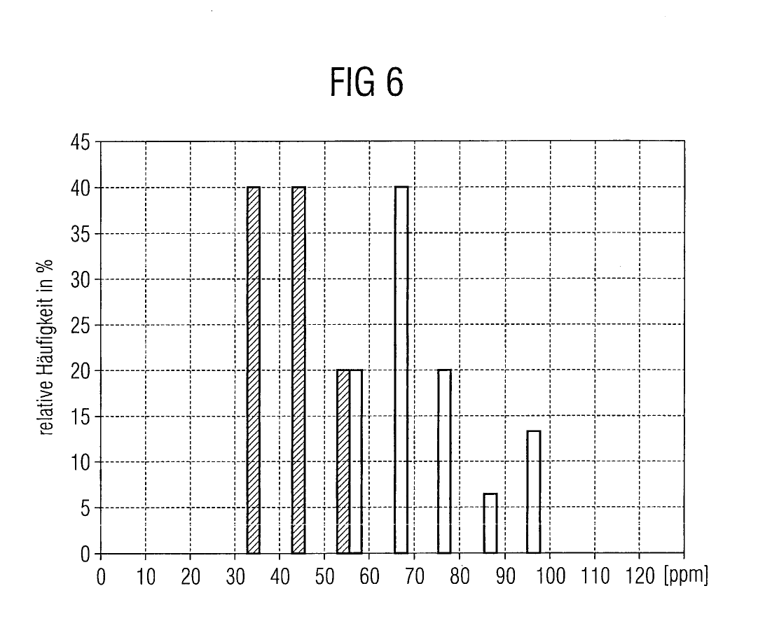

FIG. 6 is a graph representing the improved standard deviation of a characteristic variable of the component.

The exemplary embodiment is that of a surface acoustic wave (SAW) resonator to be mounted in a ceramic housing using die bonding. The housing is structured with a ceramic multiple-layer technique that is also employed in producing the housing walls. As housings become smaller, and their floors and walls become thinner, the ceramic multiple-layer technique incorporates the pressing of the individual layers that is necessary in lamination or sintering, thus creating slack in the housing and, often, uneven housing floors. FIG. 1 shows the lower part (housing floor and housing walls) of the component housing into which the component substrate is to be glued. The housing wall GW, whose small thickness may cause greater variation of the housing geometry, is also shown. Indicated on the floor of the lower housing part are metallized connecting surfaces AF, which serve later in the electrical connection to the component, e.g., via bonding wires. A predetermined pattern of spacing structures AS is pressed, for example, through a screening process onto the substrate carrier ST, i.e., the floor of the lower housing part. In FIG. 1, the spacing structures are three identical, nearly dot-shaped structures that are evenly distributed over the base surface of the substrate limited by the dashed line BS. The uniform height of the spacing structures AS is assured by the application process, but can be additionally corrected.

In the exemplary embodiment according to FIG. 2, four spacing structures AS are provided in the vicinity of the four corners of the component substrate BS, and form the corresponding contact points. The number of spacing structures or contact points can be increased for larger components or substrates.

FIG. 3 shows two parallel, strip-shaped contact structures, which also form strip-shaped contact surfaces.

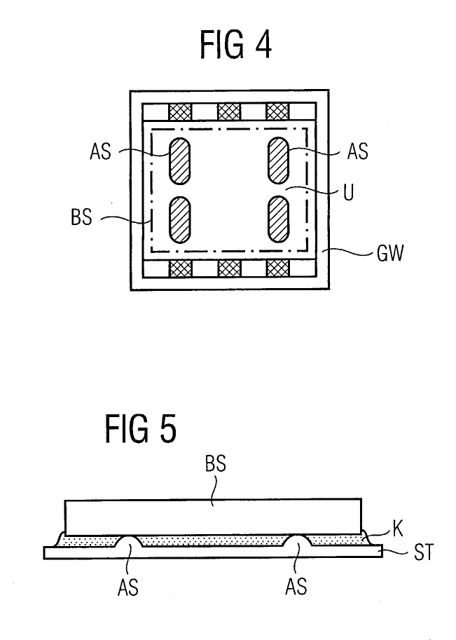

FIG. 4 shows an advantageous variation of strip-shaped spacing structures AS. In this case as well, two strip-shaped spacing structures AS are provided. They have a recess or break U in the center, however. This creates four separate contact surfaces. The break in the center of the strip-shaped spacing structures AS provides the advantage that excess glue can enter the recesses when the component substrate BS is positioned, and therefore, be better distributed. This increases the reliability of the method by simplifying the positioning of the substrate on the contact surfaces.

FIG. 5 is a schematic cross-section of a completed glued spot. It is apparent that the surfaces of the component substrate BS and the system carrier ST that are facing one another or are glued together are oriented parallel to one another due to the identical spacing structures AS. The spacing structures are shown as having a semispherical cross-section. The cross-sectional shape, however, is not mandated, and is essentially dependent on the production method employed for the spacing structures. Screening can be used to produce structures that are also nearly rectangular in cross-section and only have rounded edges. Other cross-sections are also conceivable. The only critical factor is that the contact points or contact surfaces lie in one plane or nearly in one plane.

The glue K, which is applied to one of the two surfaces of the substrate or system carrier and is uniformly distributed, without containing air, after the two parts are joined. The glue can be metered in such a quantity that it fills the entire space between the system carrier ST and the component substrate BS. If the spacing structures AS are spaced sufficiently far apart, it is also possible for the base surface of the component substrate BS to match the surface limited by the spacing structures AS. Particularly in surface acoustic wave components, this has the advantage that the entire surface (base surface) of the substrate BS is dampened by the glue layer. For example, the layer damps disturbs volume waves, thus preventing them from reflecting into the component structures. Stresses in the substrate are also transmitted or distributed better.

FIG. 6 illustrates scattering of a characteristic variable of a component that is sensitive to stresses in its substrate for components glued in accordance with the invention, in comparison to components glued with conventional methods. With the use of a surface acoustic wave resonator having a quartz substrate, the standard deviation of the resonator's mean frequencies was determined within each test batch of substrates possessing exemplary dimensions of 2.9×1.75 mm². The relative frequency of occurrence of a particular standard deviation is recorded as a percentage. The hatched bars indicate the values for components glued in accordance with the invention, while the plain bars indicate the measured results for conventionally glued components. It is readily apparent that the standard deviation is significantly reduced with the invention. As a result, more components lie within the required tolerance values, which reduces the rejection rate of the gluing method and the overall production of the component. This represents a considerable cost savings for the method overall.

The illustrated embodiments merely offer exemplary embodiments of the invention. The invention is not limited to them. In other possible embodiments, virtually all of the parameters can be varied.

1. A component in which a crystalline substrate (BS) having SAW component structures is connected by a glue (K) to a system carrier (ST),
in which the system carrier forms the lower part of a ceramic housing and has an uneven surface;
in which spacing structures (AS) are disposed between the substrate and the system carrier in a regular and defined pattern such that they create contact points or surfaces, all located in one plane, for the substrate;
in which flat surfaces of the substrate and the system carrier are oriented at a defined angle, or virtually parallel, relative to one another; and
in which the space between the spacing structures (AS), the substrate (BS) and the system carrier (ST) is partially or completely filled with glue (K).

2. The component according to claim 1, in which flat surfaces of the substrate (BS) and the system carrier (ST) are oriented virtually parallel to one another.

3. The component according to claim 1 or 2, in which the spacing structures (AS) have dot-shaped contact points.

4. The component according to claim 3, in which two, three or four dot-shaped contact points (AS) are provided.

5. The component according to claim 1, in which strip-shaped spacing structures (AS) are provided, the structures forming parallel, strip-shaped contact surfaces.

6. The component according to claim 5, in which two parallel, strip-shaped spacing structures (AS) are provided, the structures respectively having a break (U) in the center, thereby forming four separate, strip-shaped contact surfaces.

7. The component according to one of claims 1 through 6, in which the spacing structures (AS) comprise a screenable mass, and are screened onto the system carrier (ST) or the substrate (BS).

8. The component according to one of claims 1 through 6, in which the spacing structures (AS) comprise an organic or inorganic material, and are glued to the system carrier (ST).

9. The component according to one of claims 1 through 8, the component being embodied as a frequency-accurate, surface acoustic wave component.

10. A method for limiting the error scattering in the gluing of stress-sensitive SAW components (BS) having a system carrier (ST), which has a flat but uneven surface and forms the lower part of a ceramic component housing (ST, GW),
in which spacing structures (AS) are created on or mounted to the surface of the system carrier prior to gluing such that the structures form contact points or surfaces, all lying in one plane, for the component (BS);
in which glue (K) is applied to one of the surfaces;
in which the component (BS) is positioned on the contact points or surfaces; and
in which the glue is cured at a high temperature.

11. The method according to claim 10, in which the spacing structures (AS) are applied through screening.

12. The method according to claim 10 or 11, in which the spacing structures are created with a height of 20 to 50 μm.

13. The method according to one of claims 10 through 12, in which strip-shaped spacing structures (AS) that are interrupted (U) in the center are mounted; in which so much glue (K) is applied to one of the surfaces that, after the positioning, the space between the spacing structures (AS) and the two surfaces is filled with glue.

14. The method according to one of claims 10 through 12, in which a frequency-accurate, surface acoustic wave component is glued into a housing (ST, GW).

15. The use of the method according to one of claims 10 through 12 for stabilizing the mean frequency of frequency-accurate, surface acoustic wave components.
